(19) United States
(12) Patent Application Publication
(10) Pub. No.: US 2025/0142940 A1
(43) Pub. Date: May 1, 2025

(54) SEMICONDUCTOR DEVICE INCLUDING GATE DIELECTRICS OF DIFFERENT THICKNESSES AND METHOD FOR MANUFACTURING THE SAME

(71) Applicant: TAIWAN SEMICONDUCTOR MANUFACTURING COMPANY, LTD., Hsinchu (TW)

(72) Inventors: Chuan-Cheng TSOU, Hsinchu (TW); Po-Yuan SU, Hsinchu (TW); Sung-Hsin YANG, Hsinchu (TW); Jung-Chi JENG, Hsinchu (TW); Chen-Chieh CHIANG, Hsinchu (TW)

(73) Assignee: TAIWAN SEMICONDUCTOR MANUFACTURING COMPANY, LTD., Hsinchu (TW)

(21) Appl. No.: 18/495,189

(22) Filed: Oct. 26, 2023

(51) Int. Cl. H01L 21/8234; H01L 27/088; H01L 29/423; H01L 29/66; H01L 29/78

(52) U.S. Cl. CPC H10D 84/038; H10D 30/024; H10D 30/6211; H10D 64/021; H10D 64/514; H10D 84/0144; H10D 84/0158; H10D 84/834

(57) ABSTRACT

A method for manufacturing a semiconductor device includes: forming a first fin portion and a second fin portion on a semiconductor substrate, the first fin portion and the second fin portion being spaced apart from each other; and forming a first gate dielectric layer and a second gate dielectric layer on the first fin portion and the second fin portion, respectively, the first gate dielectric layer having a first thickness, the second gate dielectric layer having a second thickness different from the first thickness.

### BACKGROUND

With mature development of semiconductor technology, semiconductor devices (e.g., fin field-effect transistors (FinFETs)) have been applied in various fields. As application needs for the semiconductor devices gradually increase, device performance requirement for the semiconductor devices also increases. For example, FinFETs have been applied in image sensor processors (ISPs), and in order to meet application needs and image quality requirements of the ISPs, improvements in the manufacturing process of the FinFETs and on the device performance of the FinFETs are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 11 are schematic views illustrating some intermediate stages of the method as depicted in FIG. 1 in accordance with some embodiments.

FIG. 12 is a flow diagram illustrating a method for manufacturing a semiconductor device in accordance with some embodiments.

FIGS. 13 to 19 are schematic views illustrating some intermediate stages of the method as depicted in FIG. 12 in accordance with some embodiments.

FIG. 20 is a flow diagram illustrating a method for manufacturing a semiconductor device in accordance with some embodiments.

FIGS. 21 to 27 are schematic views illustrating some intermediate stages of the method as depicted in FIG. 20 in accordance with some embodiments.

FIG. 28 is a flow diagram illustrating a method for manufacturing a semiconductor device in accordance with some embodiments.

FIGS. 29 to 33 are schematic views illustrating some intermediate stages of the method as depicted in FIG. 28 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “top,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

In recent years, semiconductor devices have been applied in various fields (e.g., image sensor processors (ISPs)), and application need for the semiconductor devices gradually increases. An integrated circuit (IC) chip may include a plurality of semiconductor devices, for example, but not limited to, fin field-effect transistors (FinFETs)), which can be used in ISPs. Requirements of electrical performance of the FinFETs may vary depending on application needs in the ISPs. For example, the FinFETs used in the ISP may include, for example, but not limited to, core FinFETs applied in a low voltage device, FinFETs applied in an electrical device with a low random telegraph signal (RTS) noise, and input/output (I/O) FinFETs applied in a high voltage device. In this case, an increased thickness of a gate dielectric of a FinFET used in the I/O FinFETs is conducive to enhancing the high voltage capability and quality image performance of the ISP, but may result in worsening of RTS noise (which may adversely affect circuit performance of the ISP). In view of above, if the thickness of the gate dielectric of each of the FinFETs included in an IC chip is identical and large, the FinFETs may only be applied in some high voltage electrical devices (e.g., the I/O FinFET devices), resulting in a limitation on application thereof.

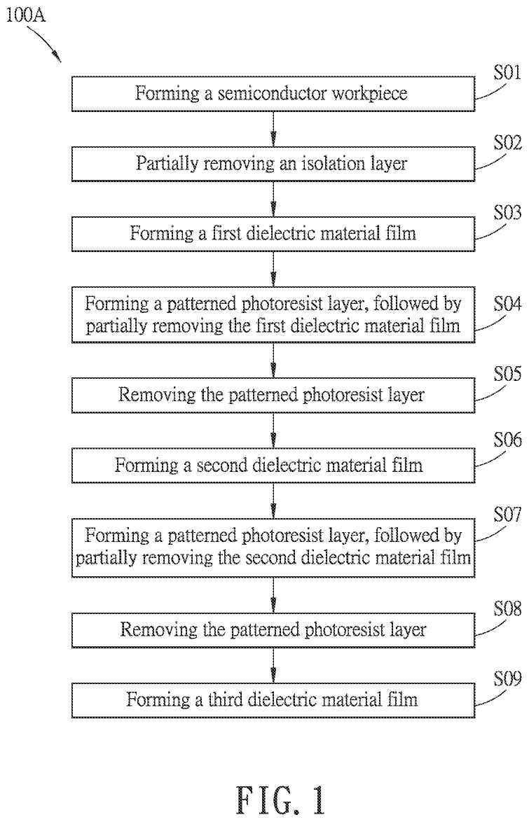

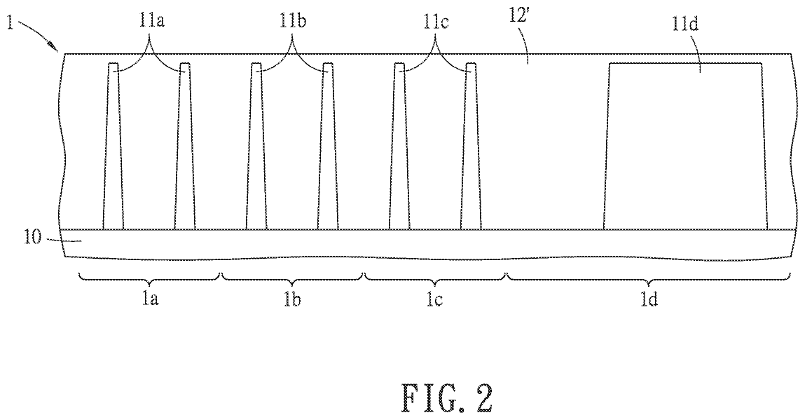

The present disclosure is directed to a semiconductor device and a method for manufacturing the same. FIG. 1 is a flow diagram illustrating a method 100A for manufacturing a semiconductor device 200A shown in FIG. 11 in accordance with some embodiments. FIGS. 2 to 10 illustrate schematic views of some intermediate stages of the method 100A. Some portions may be omitted in FIGS. 2 to 10 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step S01, where a semiconductor workpiece 1 is formed. The semiconductor workpiece 1 includes a semiconductor substrate 10, a plurality of fin portions 11a, 11b, 11c, 11d, and an isolation layer 12′.

The semiconductor substrate 10 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable materials for the compound semiconductor are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 10 may include a multilayer compound semiconductor structure. In some embodiments, the semiconductor substrate 10 may be a semiconductor on insulator (SOI) (e.g., silicon germanium on insulator (SGOI)). Generally, an SOI substrate includes a layer of a semiconductor material, such as epitaxial silicon (Si), germanium (Ge), silicon germanium (SiGe), or combinations thereof. The SOI substrate may be doped with a P-type dopant, for example, but not limited to, boron (Br), aluminum (Al), or gallium (Ga). Other suitable P-type dopant materials are within the contemplated scope of the present disclosure. Alternatively, the SOI substrate may be doped with an N-type dopant, for example, but not limited to, nitrogen (N), phosphorus (P), or arsenic (As). Other suitable N-type dopant materials are within the contemplated scope of the present disclosure. In some embodiments, the semiconductor substrate 10 may include a first region 1a, a second region 1b, a third region 1c, and a fourth region 1d.

The fin portions 11a, 11b, 11c, 11d are disposed on the semiconductor substrate 10, and are spaced apart from each other. Each of the fin portions 11a, 11b, 11c, 11d are made of a semiconductor material, for example, but not limited to, silicon (Si). Other suitable semiconductor materials for the fin portions 11a, 11b, 11c, 11d are within the contemplated scope of the present disclosure. In some embodiments, the fin portions 11a are located in the first region 1a, the fin portions 11b are located in the second region 1b, the fin portions 11c are located in the third region 1c, and the fin portion 11d is located in the fourth region 1d. In some embodiments, the fin portions 11a, 11b, 11c may be applied in a plurality of fin field-effect transistors (FinFETs). In some embodiments, the fin portion 11d may be applied in a planar FET.

The isolation layer 12′ is disposed on the semiconductor substrate 10, and covers the fin portions 11a, 11b, 11c, 11d. In some embodiments, the isolation layer 12′ may be made of an oxide-based material (e.g., silicon oxide), a nitride-based material (e.g., silicon nitride), or a combination thereof. Other suitable materials for the isolation layer 12′ are within the contemplated scope of the present disclosure.

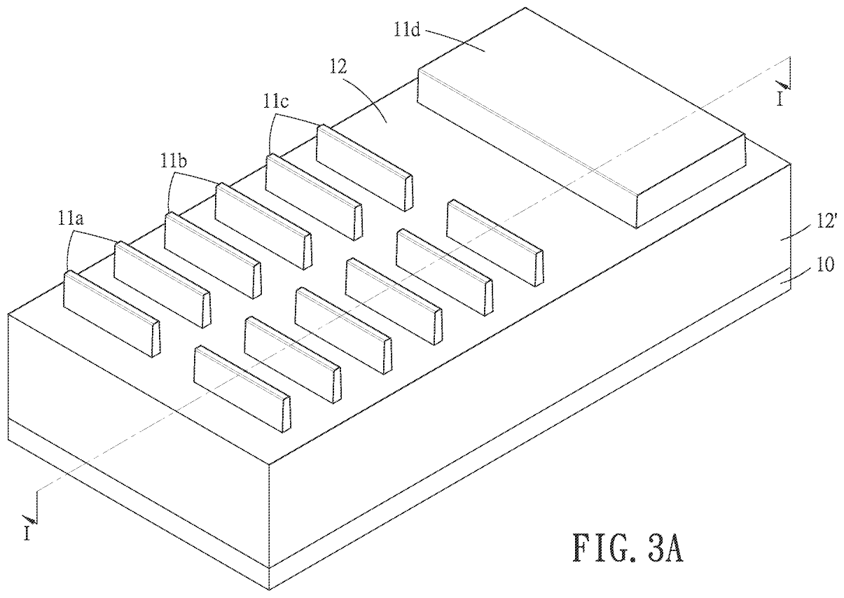

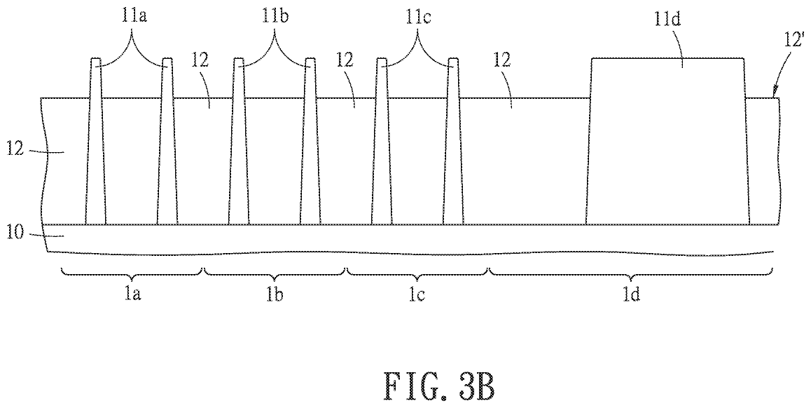

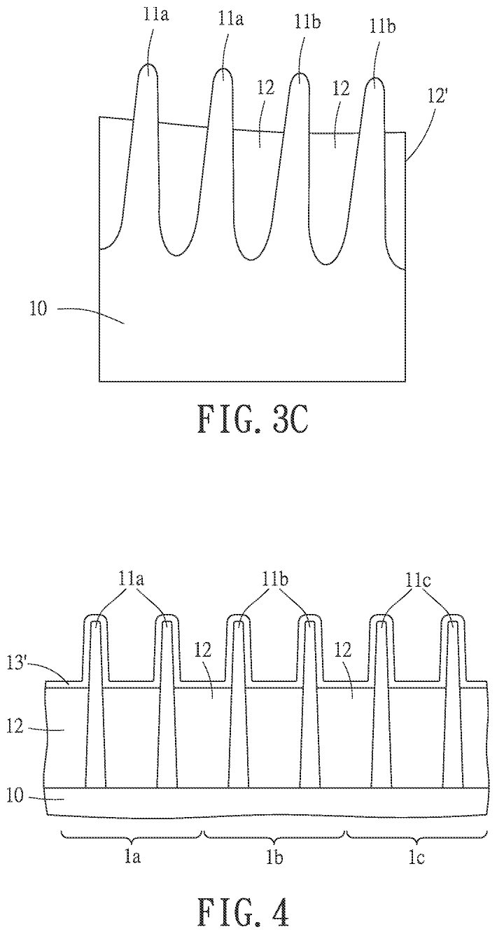

Referring to FIG. 1 and the example illustrated in FIGS. 3A to 3C, the method 100A then proceeds to step S02, where the isolation layer 12′ is partially removed. FIG. 3B illustrates a cross-sectional view taken along line I-I of FIG. 3A. FIG. 3C is a partially schematic view of FIG. 3B. Step S02 may be performed by a suitable etching process, for example, but not limited to, a dry etching, a wet etching, a combination thereof, or other suitable etching processes. In some embodiments, in this step, a dry etching process and a wet etching process may be sequentially performed on the structure shown in FIG. 2 to partially remove the isolation layer 12′. In this case, the dry etching process may be an anisotropic etching process or other suitable etching processes, and the wet etching process may be performed by sequentially using a dilute hydrofluoric acid (DHF)), a sulfuric acid peroxide mixture (SPM), and an ammonium hydroxide peroxide mixture (APM or may be referred to as SC-1) to etch the isolation layer 12′. In some embodiments, after this step, a B-clean process may be performed to remove residues formed on the structure shown in FIG. 3A (or FIG. 3B). The B-clean process may be performed by sequentially using an ozone solution in a deionized water, a hydrochloric peroxide mixture (HPM or may be referred to as SC-2), and the APM. After the isolation layer 12′ is partially removed, the fin portions 11a, 11b, 11c, 11d protrude upwardly out of the isolation layer 12′, and the isolation layer 12′ is formed with a plurality of isolation portions 12. Two adjacent ones of the isolation portions 12 are respectively located at two opposite sides of a corresponding one of the fin portions 11a, 11b, 11c, 11d. In some embodiments, each of the isolation portions 12 may be a portion of a shallow trench isolation (STI), a deep trench isolation (DTI), or other suitable isolation structures.

Referring to FIG. 1 and the example illustrated in FIG. 4, the method 100A then proceeds to step S03, where a first dielectric material film 13′ is conformally formed on the structure shown in FIG. 3A (or FIG. 3B). The fin portion 11d and the fourth region 1d are not shown in FIG. 4. Step S03 may be performed by a suitable deposition process, for example, but not limited to, thermal in situ steam generation (ISSG), chemical vapor deposition (CVD), thermal CVD, plasma-enhanced atomic layer deposition (PEALD), plasma-enhanced CVD (PECVD), high density plasma CVD (HDP-CVD), flowable oxide deposition, or other suitable deposition processes. The first dielectric material film 13′ may be made of a dielectric material, for example, but not limited to, an oxide-based material (e.g., silicon oxide), a nitride-based material (e.g., silicon nitride), a high dielectric constant material (e.g., hafnium oxide, hafnium silicate, hafnium silicon oxynitride, hafnium tantalum oxide, hafnium titanium oxide, hafnium zirconium oxide, or other suitable high dielectric constant materials), or combinations thereof. Other suitable dielectric materials for forming the first dielectric material film 13′ are within the contemplated scope of the present disclosure. In some embodiments, the first dielectric material film 13′ may have a thickness ranging from about 0.1 nm to about 10 nm. In some embodiments, after this step, an annealing process may be performed on the structure shown in FIG. 4. In some embodiments, an annealing temperature for the annealing process may range from about 500° C. to about 1600° C. In some embodiments, the annealing process may be omitted in this step.

As shown in FIGS. 5A and 5B, in some embodiments, a uniformity of the first dielectric material film 13′ formed by PEALD (see FIG. 5A) is better than that of the first dielectric material film 13′ formed by thermal ISSG (see FIG. 5B).

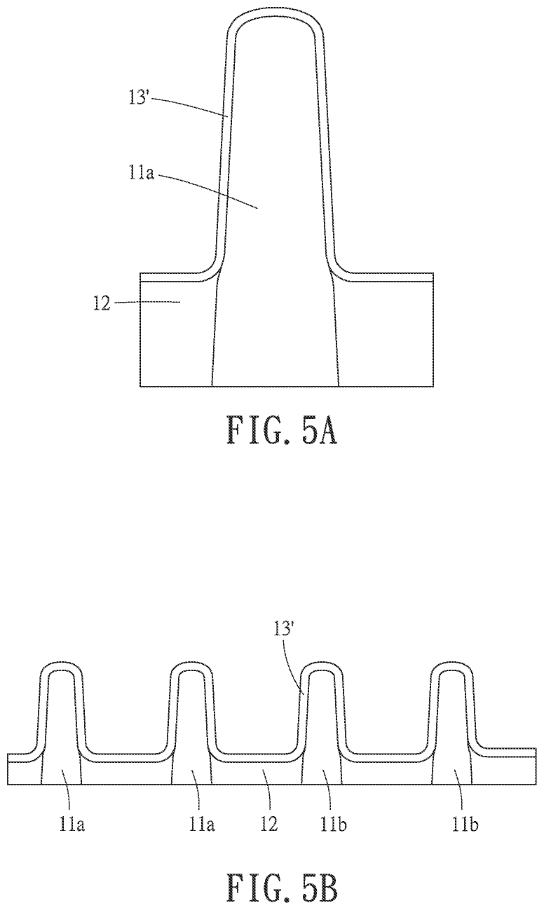

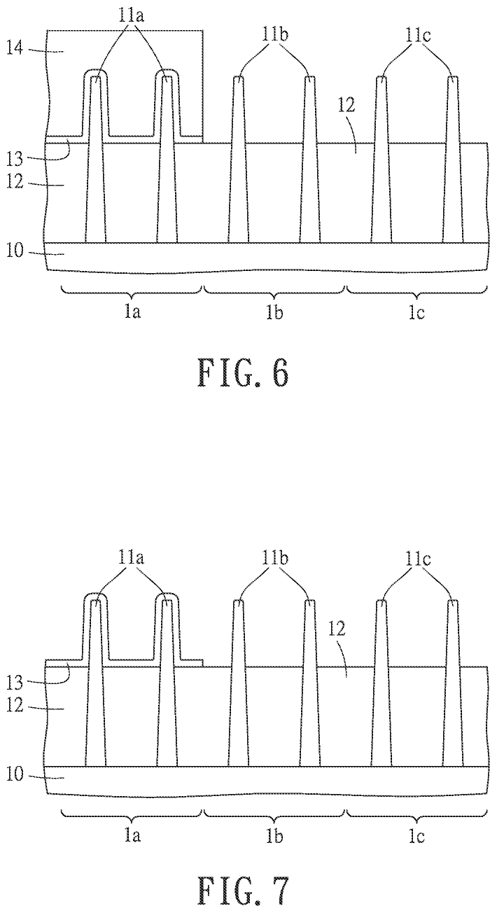

Referring to FIG. 1 and the example illustrated in FIG. 6, the method 100A then proceeds to step S04, where a patterned photoresist layer 14 is formed, followed by partially removing the first dielectric material film 13′. In this step, the patterned photoresist layer 14 covers the fin portions 11a in the first region 1a of the semiconductor substrate 10. The patterned photoresist layer 14 may be formed using a photolithography technique (without an etching process). The photolithography technique may include, for example, but not limited to, coating a photoresist layer (not shown) on the structure shown in FIG. 4, soft-baking the photoresist layer, exposing the photoresist layer through a photomask (not shown), post-exposure baking the photoresist layer, developing the photoresist layer, hard-baking the photoresist layer, so as to form the patterned photoresist layer 14. In some embodiments, after formation of the patterned photoresist layer 14, a descum process may be performed to remove residues of the photoresist layer remaining on the fin portions 11b, 11c. After the formation of the patterned photoresist layer 14, a portion of the first dielectric material film 13′ exposed from the patterned photoresist layer 14 (for example, a portion of the first dielectric material film 13′ disposed in the second and third regions 1b, 1c shown in FIG. 4) is removed by a suitable etching process, for example, but not limited to, dry etching, wet etching, a combination thereof, or other suitable etching processes. After this step, the first dielectric material film 13′ is formed into a first gate dielectric film 13.

Referring to FIG. 1 and the example illustrated in FIG. 7, the method 100A then proceeds to step S05, where the patterned photoresist layer 14 of the structure shown in FIG. 6 is removed. Step S05 may be performed by a suitable removal process, for example, but not limited to, an etching process, an ashing process, or other suitable removal processes. In some embodiments, the etching process may be performed using the SPM to remove the patterned photoresist layer 14.

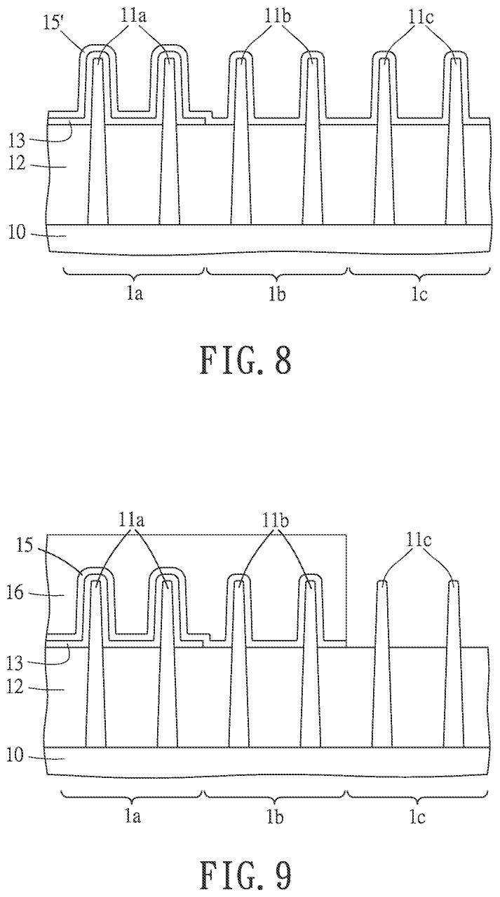

Referring to FIG. 1 and the example illustrated in FIG. 8, the method 100A then proceeds to step S06, where a second dielectric material film 15′ is formed on the structure shown in FIG. 7. The material and process for forming the second dielectric material film 15′ may be the same as or similar to those for forming the first dielectric material film 13′, and thus details thereof are omitted for the sake of brevity. The second dielectric material film 15′ may have a thickness ranging from about 0.1 nm to about 10 nm. In some embodiments, after this step, the annealing process as described in step S03 may be performed on the structure shown in FIG. 8. In some embodiments, the annealing process may be omitted in this step.

Referring to FIG. 1 and the example illustrated in FIG. 9, the method 100A then proceeds to step S07, where a patterned photoresist layer 16 is formed, followed by partially removing the second dielectric material film 15′ of the structure shown in FIG. 8. In this step, the patterned photoresist layer 16 covers the structure in the first and second regions 1a, 1b of the semiconductor substrate 10. The patterned photoresist layer 16 may be formed using a photolithography technique which is the same as that described in step S04. After formation of the patterned photoresist layer 16, a portion of the second dielectric material film 15′ exposed from the patterned photoresist layer 16 (for example, a portion of the second dielectric material film 15′ disposed in the third regions 1c shown in FIG. 8) is removed by a suitable etching process, for example, but not limited to, dry etching, wet etching, a combination thereof, or other suitable etching processes. After this step, the second dielectric material film 15′ is formed into a second gate dielectric film 15.

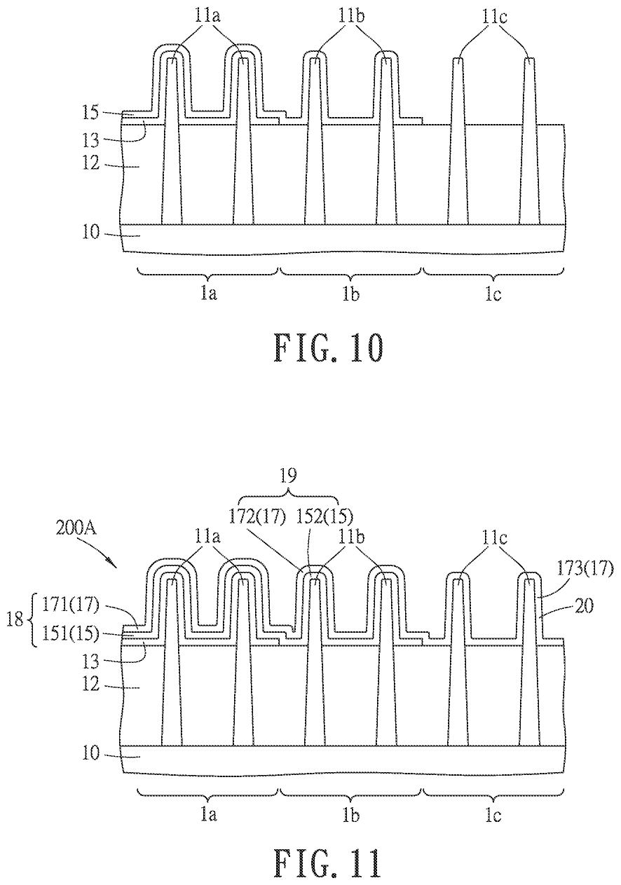

Referring to FIG. 1 and the example illustrated in FIG. 10, the method 100A then proceeds to step S08, where the patterned photoresist layer 16 of the structure shown in FIG. 9 is removed. Step S08 may be performed by a suitable removal process, for example, but not limited to, an etching process, an ashing process, or other suitable removal processes. In some embodiments, the etching process may be performed using the SPM to remove the patterned photoresist layer 16.

Referring to FIG. 1 and the example illustrated in FIG. 11, the method 100A then proceeds to step S09, where a third dielectric material film is formed on the structure shown in FIG. 10. The material and process for forming the third dielectric material film may be the same as or similar to those for forming the first dielectric material film 13′, and thus details thereof are omitted for the sake of brevity. The third dielectric material film may have a thickness ranging from about 0.1 nm to about 10 nm. After this step, the third dielectric material film is formed into a third gate dielectric film 17. In some embodiments, after this step, the annealing process as described in step S03 may be performed on the structure shown in FIG. 11.

After step S09, the semiconductor device 200A is obtained. In the first region 1a of the semiconductor substrate 10, a first gate dielectric layer 18 is disposed on the isolation portions 12 and covers the fin portions 11a. The first gate dielectric layer 18 includes the first gate dielectric film 13, a first portion 151 of the second gate dielectric film 15 and a first portion 171 of the third gate dielectric film 17, and has a first thickness. In the second region 1b of the semiconductor substrate 10, a second gate dielectric layer 19 is disposed on the isolation portions 12 and covers the fin portions 11b. The second gate dielectric layer 19 includes a second portion 152 of the second gate dielectric film 15 and a second portion 172 of the third gate dielectric film 17, and has a second thickness. In the third region 1c of the semiconductor substrate 10, a third gate dielectric layer 20 is disposed on the isolation portions 12 and covers the fin portions 11c. The third gate dielectric layer 20 includes a third portion 173 of the third gate dielectric film 17, and has a third thickness. In some embodiments, the second thickness of the second gate dielectric layer 19 is less than the first thickness of the first gate dielectric layer 18, and the third thickness of the third gate dielectric layer 20 is less than the second thickness of the second gate dielectric layer 19. In some embodiments, when the first thickness of the first gate dielectric layer 18 ranges from about 4 nm to about 8 nm, the fin portions 11a covered with the first gate dielectric layer 18 may be used for forming a FinFET to be applied in a high voltage electrical device (e.g., an I/O device having an operation voltage of about 3 V and a breakdown voltage of at least about 2.5 V). In some embodiments, when the second thickness of the second gate dielectric layer 19 ranges from about 3 nm to about 5 nm, the fin portions 11b covered with the second gate dielectric layer 19 may be used for forming a FinFET to be applied in a low voltage electrical device (e.g., a core device having an operation voltage of about 1.8 V and a breakdown voltage of at least about 2.5 V). In some embodiments, when the third thickness of the third gate dielectric layer 20 ranges from about 2 nm to about 5 nm, the fin portions 11c covered with the third gate dielectric layer 20 may be used for forming a FinFET to be applied in an electrical device having a low RTS.

In some embodiments, steps S07 to S09 may be repeated to form at least one additional dielectric material film on the third gate dielectric film 17, so as to form at least one additional gate dielectric layer disposed on additional fin portions (not shown) and having a thickness less than that of the third gate dielectric layer 20.

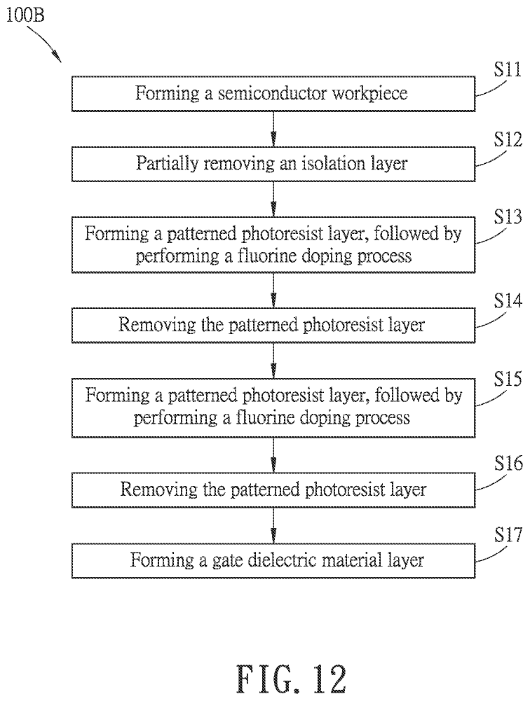

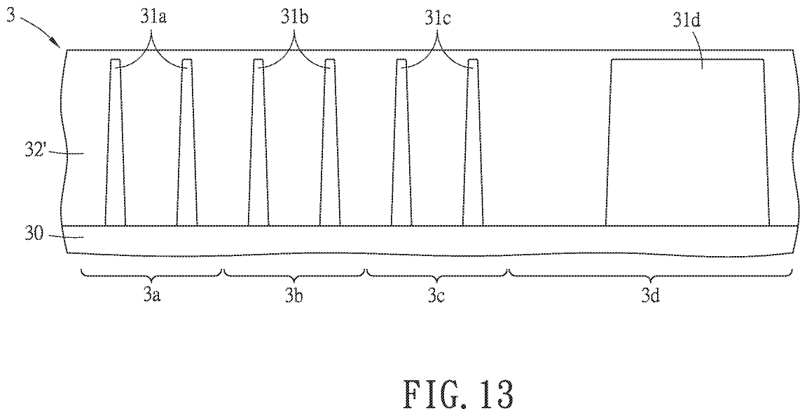

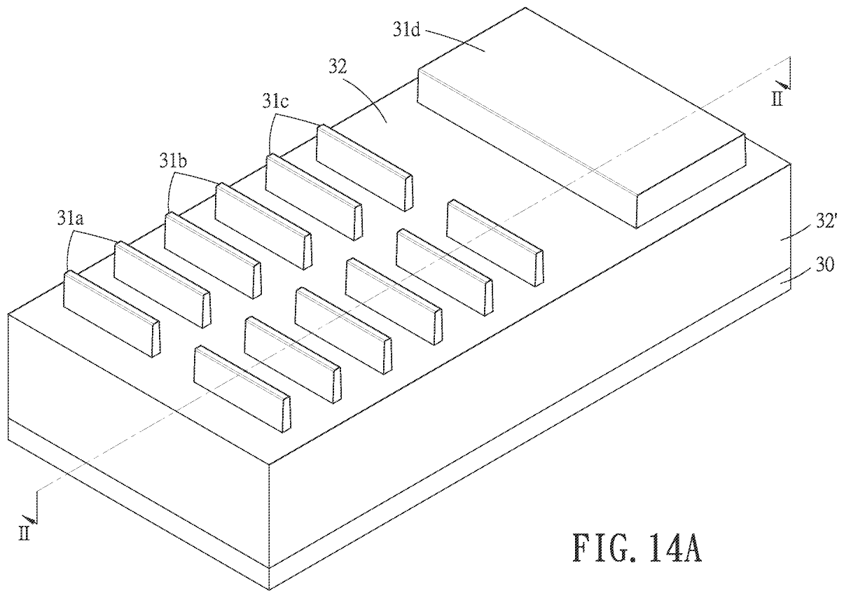

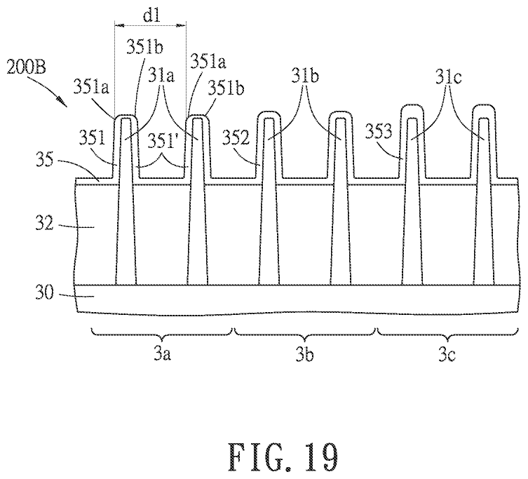

FIG. 12 is a flow diagram illustrating a method 100B for manufacturing a semiconductor device 200B shown in FIG. 19 in accordance with some embodiments. FIGS. 13 to 18 illustrate schematic views of some intermediate stages of the method 100B. Some portions may be omitted in FIGS. 13 to 18 for the sake of brevity. Additional steps can be provided before, after or during the method 100B, and some of the steps described herein may be replaced by other steps or be eliminated.

Referring to FIG. 12 and the example illustrated in FIG. 13, the method 100B begins at step S11, where a semiconductor workpiece 3 is formed. The semiconductor workpiece 3 includes a semiconductor substrate 30, a plurality of fin portions 31a, 31b, 31c, 31d, and an isolation layer 32′. The material of the semiconductor substrate 30 may be the same as or similar to that of the semiconductor substrate 10 as described in step S01 of the method 100A, and thus details thereof are omitted for the sake of brevity. The fin portions 31a, 31b, 31c, 31d are disposed on the semiconductor substrate 30, and are spaced apart from each other. The material of the fin portions 31a, 31b, 31c, 31d may be the same as or similar to that of the fin portions 11a, 11b, 11c, 11d as described in step S01 of the method 100A, and thus details thereof are omitted for the sake of brevity. The isolation layer 32′ is disposed on the semiconductor substrate 30, and covers the fin portions 31a, 31b, 31c, 31d. The material of the isolation layer 32′ may be the same as or similar to that of the isolation layer 12′ as described in step S01 of the method 100A, and thus details thereof are omitted for the sake of brevity. In some embodiments, the semiconductor substrate 30 may include a first region 3a, a second region 3b, a third region 3c, and a fourth region 3d. In some embodiments, the fin portions 31a are located in the first region 3a, the fin portions 31b are located in the second region 3b, the fin portions 31c are located in the third region 3c, and the fin portion 31d is located in the fourth region 3d.

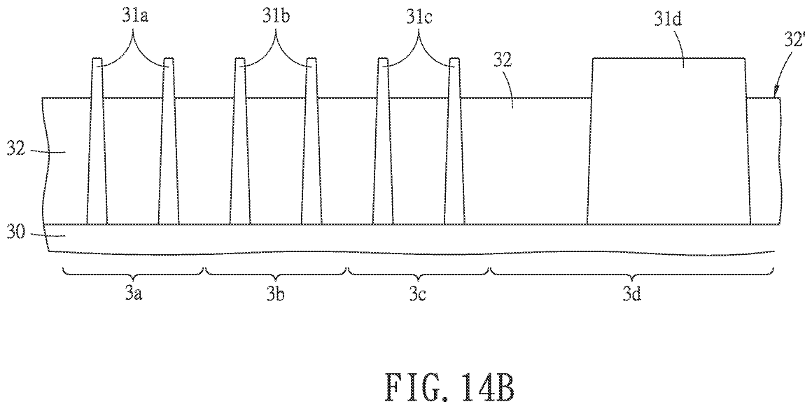

Referring to FIG. 12 and the example illustrated in FIGS. 14A and 14B, the method 100B then proceeds to step S12, where the isolation layer 32′ is partially removed. FIG. 14B illustrates a cross-sectional view taken along line II-II of FIG. 14A. Step S12 is the same as step S02 of the method 100A, and thus details thereof are omitted for the sake of brevity. After the isolation layer 32′ is partially removed, the fin portions 31a, 31b, 31c, 31d protrude upwardly out of the isolation layer 32′, and the isolation layer 32′ is formed with a plurality of isolation portions 32. Two adjacent ones of the isolation portions 32 are respectively located at two opposite sides of a corresponding one of the fin portions 31a, 31b, 31c, 31d.

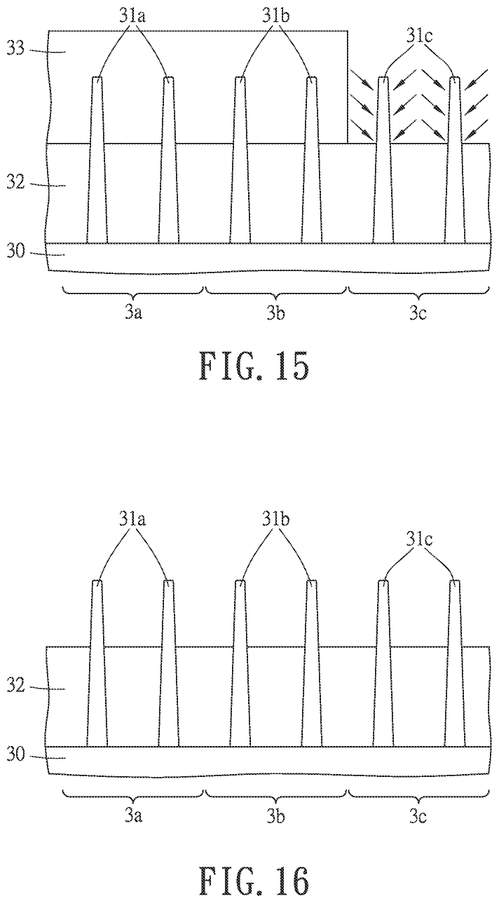

Referring to FIG. 12 and the example illustrated in FIG. 15, the method 100B then proceeds to step S13, where a patterned photoresist layer 33 is formed, followed by performing a fluorine doping process. The fin portion 31d and the fourth region 3d are not shown in FIG. 15. The patterned photoresist layer 33 is formed to cover the fin portions 31a, 31b in the first and second regions 3a, 3b of the semiconductor substrate 30. The material and process for forming the patterned photoresist layer 33 may be the same as or similar to those for forming the patterned photoresist layer 14 as described in step S04 of the method 100A, and thus details thereof are omitted for the sake of brevity. The fluorine doping process is performed on the fin portions exposed from the patterned photoresist layer 33 (for example, the fin portions 31c in the third region 3c of the semiconductor substrate 30). In some embodiments, the fluorine doping process may be a fluorine implantation process. In this case, the fluorine implantation process may be performed at an energy ranging from about 1 KeV to about 400 KeV, and a dose ranging from about 1×10¹⁰ atoms/cm² to about 1×10¹⁶ atoms/cm². In alternative embodiments, the fluorine doping process may be performed by thermal diffusion. In some embodiments, the fluorine doping process may be performed using a gas that includes, for example, but not limited to, fluorine gas or boron fluoride.

Referring to FIG. 12 and the example illustrated in FIG. 16, the method 100B then proceeds to step S14, where the patterned photoresist layer 33 of the structure shown in FIG. 15 is removed. Step S14 may be performed by a suitable removal process, for example, but not limited to, an etching process, an ashing process, or other suitable removal processes.

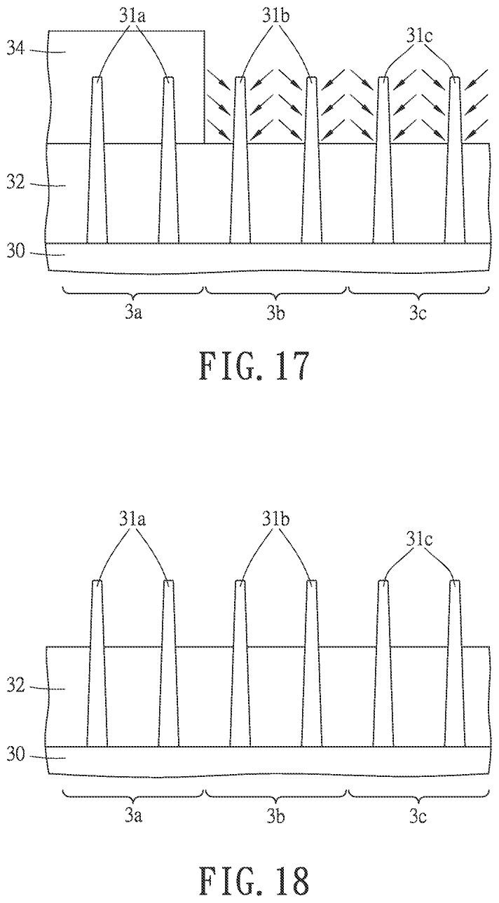

Referring to FIG. 12 and the example illustrated in FIG. 17, the method 100B then proceeds to step S15, where a patterned photoresist layer 34 is formed, followed by performing a fluorine doping process. The patterned photoresist layer 34 is formed to cover the fin portions 31a in the first region 3a of the semiconductor substrate 30. The material and process for forming the patterned photoresist layer 34 may be the same as or similar to those for forming the patterned photoresist layer 14 as described in step S04 of the method 100A, and thus details thereof are omitted for the sake of brevity. The fluorine doping process of step S15 may be performed in a manner similar to that as described in step S13. In this step, the fluorine doping process is performed on the fin portions exposed from the patterned photoresist layer 34 (for example, the fin portions 31b, 31c in the second and third regions 3b, 3c of the semiconductor substrate 30).

Referring to FIG. 12 and the example illustrated in FIG. 18, the method 100B then proceeds to step S16, where the patterned photoresist layer 34 of the structure shown in FIG. 17 is removed. Step S16 may be performed by a suitable removal process, for example, but not limited to, an etching process, an ashing process, or other suitable removal processes.

Referring to FIG. 12 and the example illustrated in FIG. 19, the method 100B then proceeds to step S17, where a gate dielectric material layer 35 is formed on the structure shown in FIG. 18. The material and process for forming the gate dielectric material layer 35 may be the same as or similar to those for forming the first dielectric material film 13′, and thus details thereof are omitted for the sake of brevity. In some embodiments, after this step, an annealing process (for example, the annealing process as described in step S03 of the method 100A) may be performed on the structure shown in FIG. 19.

After step S17, the semiconductor device 200B is obtained. As shown in FIG. 19, in some embodiments, the gate dielectric material layer 35 may include a first gate dielectric layer 351 covering the fin portions 31a in the first region 3a of the semiconductor substrate 30, a second gate dielectric layer 352 covering the fin portions 31b in the second region 3b of the semiconductor substrate 30, and a third gate dielectric layer 353 covering the fin portions 31c in the third region 3c of the semiconductor substrate 30. In some embodiments, a thickness of the first gate dielectric layer 351 is less than a thickness of the second gate dielectric layer 352, and the thickness of the second gate dielectric layer 352 is less than a thickness of the third gate dielectric layer 353. It is noted that when the number of the fluorine doping process performed on a fin portion increases, the deposition rate of the gate dielectric material layer 35 on the fin portion increases. In this case, the fin portions 31c in the third region 3c of the semiconductor substrate 30 are subjected to the fluorine doping process twice, the fin portions 31b in the second region 3b of the semiconductor substrate 30 are subjected to the fluorine doping process once, and the fin portions 31a in the first region 3a of the semiconductor substrate 30 are not subjected to the fluorine doping process. Therefore, the deposition rate of the gate dielectric material layer 35 on the fin portions 31c is faster than that of the gate dielectric material layer 35 on the fin portions 31a, 31b, and the deposition rate of the gate dielectric material layer 35 on the fin portions 31b is faster than that of the gate dielectric material layer 35 on the fin portions 31a. The thickness of the third gate dielectric layer 353 formed on the fin portions 31c is greater than that of the second gate dielectric layer 352 formed on the fin portions 31b, and the thickness of the second gate dielectric layer 352 formed on the fin portions 31b is greater than that of the first gate dielectric layer 351 formed on the fin portions 31a.

In some embodiments, when the thickness of the first gate dielectric layer 351 ranges from about 2 nm to about 5 nm, the fin portions 31a covered with the first gate dielectric layer 351 may be used for forming a FinFET to be applied in an electrical device having a low RTS. In some embodiments, when the thickness of the second gate dielectric layer 352 ranges from about 3 nm to about 5 nm, the fin portions 31b covered with the second gate dielectric layer 352 may be used for forming a FinFET to be applied in a low voltage electrical device (e.g., a core device having an operation voltage of about 1.8 V and a breakdown voltage of at least about 2.5 V). In some embodiments, when the thickness of the third gate dielectric layer 353 ranges from about 4 nm to about 8 nm, the fin portions 31c covered with the third gate dielectric layer 353 may be used for forming a FinFET to be applied in a high voltage electrical device (e.g., an I/O device having an operation voltage of about 3 V and a breakdown voltage of at least about 2.5 V).

As shown in FIG. 19, in some embodiments, the first gate dielectric layer 351 includes a plurality of gate dielectric parts 351′ disposed on the fin portions 31a, respectively. Each of the gate dielectric parts 351′ has a first top corner 351a and a second top corner 351b opposite to each other, and the second top corner 351b of one of the gate dielectric parts 351′ is proximate to the first top corner 351a of an adjacent one of the gate dielectric parts 351′. In some embodiments, when the thickness of the first gate dielectric layer 351 increases, a pitch size (d1) between two adjacent ones of the gate dielectric parts 351′ (i.e., a distance between the first top corner 351a of one of the gate dielectric parts 351′ and the first top corner 351a of an adjacent one of the gate dielectric parts 351′) increases. In some embodiments, the pitch size (d1) may be at least about 1.2 to 2 times of the thickness of the first gate dielectric layer 351. For example, when the thickness of the first gate dielectric layer 351 ranges from about 2 nm to about 3 nm, the pitch size (d1) may be at least about 4 nm. In another example, when the thickness of the first gate dielectric layer 351 ranges from about 3 nm to about 4 nm, the pitch size (d1) may be at least about 5 nm. In yet another example, when the thickness of the first gate dielectric layer 351 is at least about 5 nm, the pitch size (d1) may be at least about 7 nm.

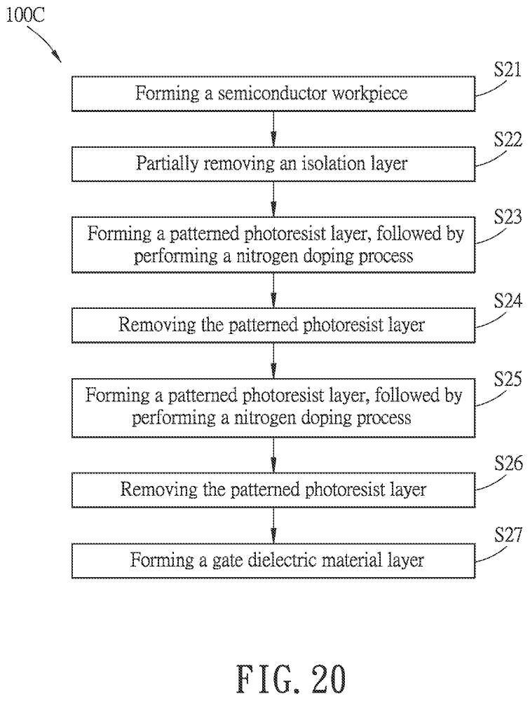

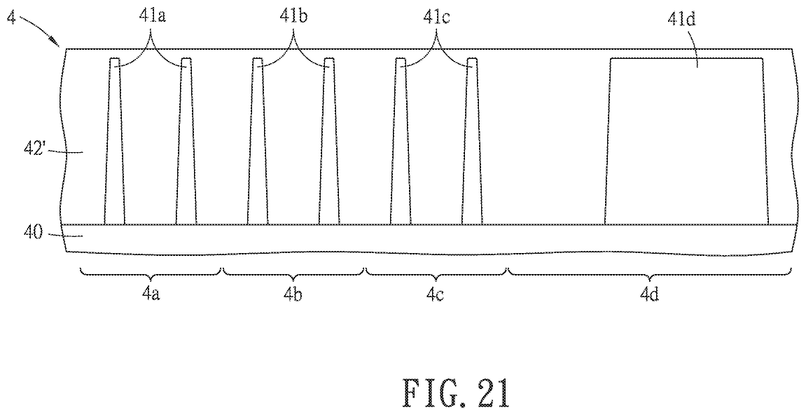

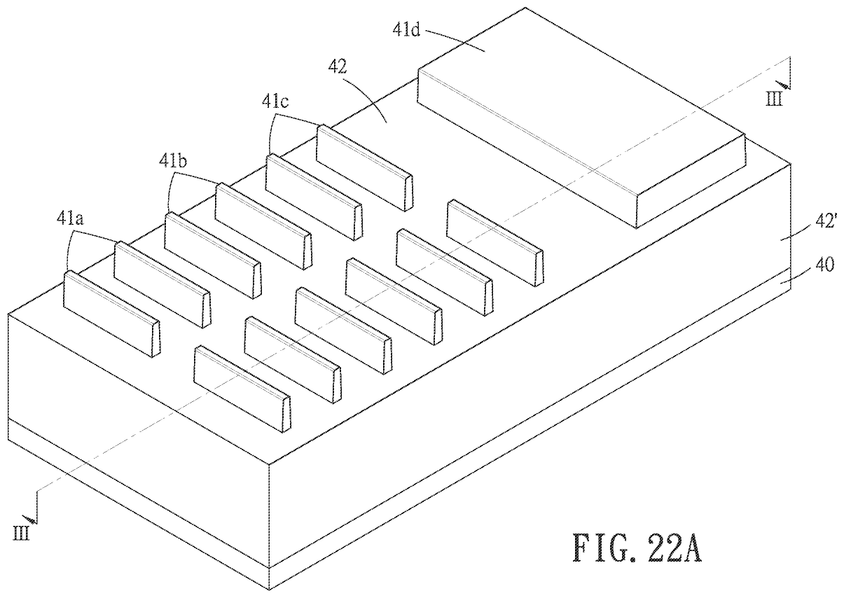

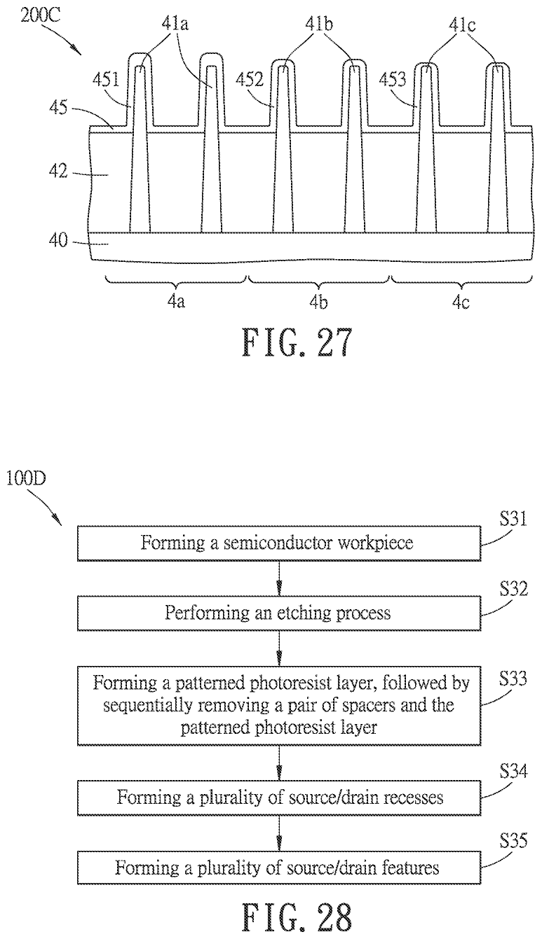

FIG. 20 is a flow diagram illustrating a method 100C for manufacturing a semiconductor device 200C shown in FIG. 27 in accordance with some embodiments. FIGS. 21 to 26 illustrate schematic views of some intermediate stages of the method 100C. Some portions may be omitted in FIGS. 21 to 26 for the sake of brevity. Additional steps can be provided before, after or during the method 100C, and some of the steps described herein may be replaced by other steps or be eliminated.

Referring to FIG. 20 and the example illustrated in FIG. 21, the method 100C begins at step S21, where a semiconductor workpiece 4 is formed. The semiconductor workpiece 4 includes a semiconductor substrate 40, a plurality of fin portions 41a, 41b, 41c, 41d, and an isolation layer 42′. The material of the semiconductor substrate 40 may be the same as or similar to that of the semiconductor substrate 10 as described in step S01 of the method 100A, and thus details thereof are omitted for the sake of brevity. The fin portions 41a, 41b, 41c, 41d are disposed on the semiconductor substrate 40, and are spaced apart from each other. The material of the fin portions 41a, 41b, 41c, 41d may be the same as or similar to that of the fin portions 11a, 11b, 11c, 11d as described in step S01 of the method 100A, and thus details thereof are omitted for the sake of brevity. The isolation layer 42′ is disposed on the semiconductor substrate 40, and covers the fin portions 41a, 41b, 41c, 41d. The material of the isolation layer 42′ may be the same as or similar to that of the isolation layer 12′ as described in step S01 of the method 100A, and thus details thereof are omitted for the sake of brevity. In some embodiments, the semiconductor substrate 40 may include a first region 4a, a second region 4b, a third region 4c, and a fourth region 4d. In some embodiments, the fin portions 41a are located in the first region 4a, the fin portions 41b are located in the second region 4b, the fin portions 41c are located in the third region 4c, and the fin portion 41d is located in the fourth region 4d.

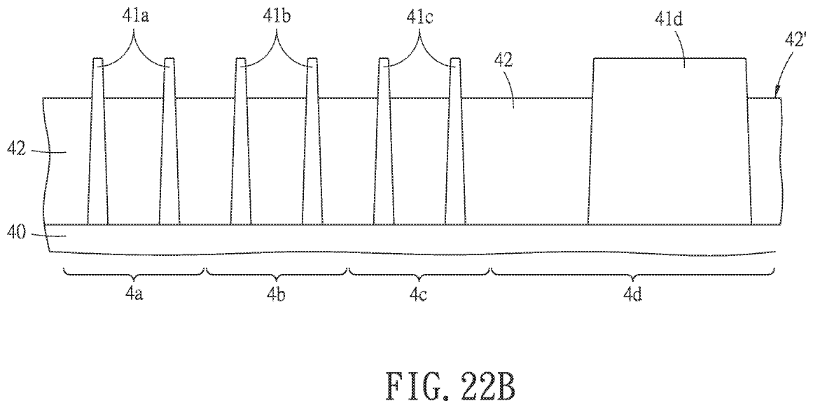

Referring to FIG. 20 and the example illustrated in FIGS. 22A and 22B, the method 100C then proceeds to step S22, where the isolation layer 42′ is partially removed. FIG. 22B illustrates a cross-sectional view taken along line III-III of FIG. 22A. Step S22 is the same as step S02 of the method 100A, and thus details thereof are omitted for the sake of brevity. After the isolation layer 42′ is partially removed, the fin portions 41a, 41b, 41c, 41d protrude upwardly out of the isolation layer 42′, and the isolation layer 42′ is formed with a plurality of isolation portions 42. Two adjacent ones of the isolation portions 42 are respectively located at two opposite sides of a corresponding one of the fin portions 41a, 41b, 41c, 41d.

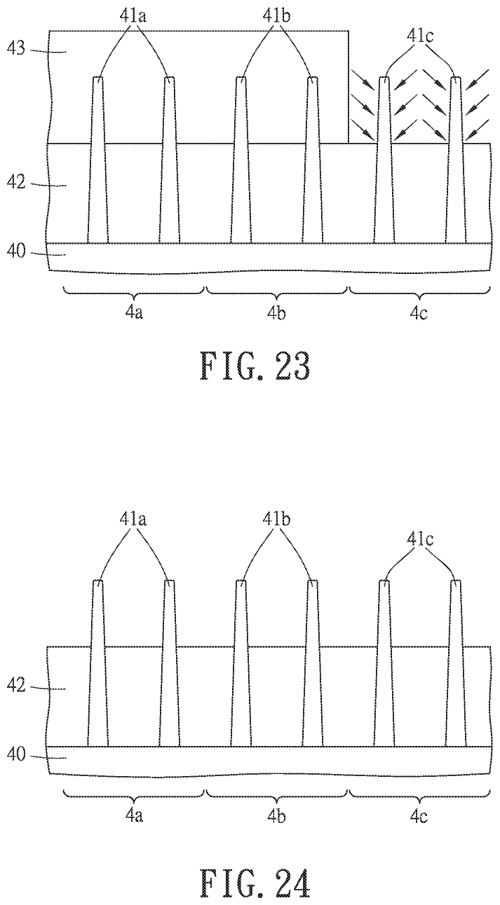

Referring to FIG. 20 and the example illustrated in FIG. 23, the method 100C then proceeds to step S23, where a patterned photoresist layer 43 is formed, followed by performing a nitrogen doping process. The fin portion 41d and the fourth region 4d are not shown in FIG. 23. The patterned photoresist layer 43 is formed to cover the fin portions 41a, 41b in the first and second regions 4a, 4b of the semiconductor substrate 40. The material and process for forming the patterned photoresist layer 43 may be the same as or similar to those for forming the patterned photoresist layer 14 as described in step S04 of the method 100A, and thus details thereof are omitted for the sake of brevity. The nitrogen doping process is performed on the fin portions exposed from the patterned photoresist layer 43 (for example, the fin portions 41c in the third region 4c of the semiconductor substrate 40). In some embodiments, the nitrogen doping process may be a nitrogen implantation process. In this case, the nitrogen implantation process may be performed at an energy ranging from about 1 KeV to about 400 KeV, and a dose ranging from about 1×10¹⁰ atoms/cm² to about 1×10¹⁶ atoms/cm². In alternative embodiments, the nitrogen doping process may be performed by thermal diffusion. In some embodiments, the nitrogen doping process may be performed using a gas that includes, for example, but not limited to, nitrogen gas, amino-silane, diamino-silane, triamino-silane, tetramino-silane, or combinations thereof.

Referring to FIG. 20 and the example illustrated in FIG. 24, the method 100C then proceeds to step S24, where the patterned photoresist layer 43 of the structure shown in FIG. 23 is removed. Step S24 may be performed by a suitable removal process, for example, but not limited to, an etching process, an ashing process, or other suitable removal processes.

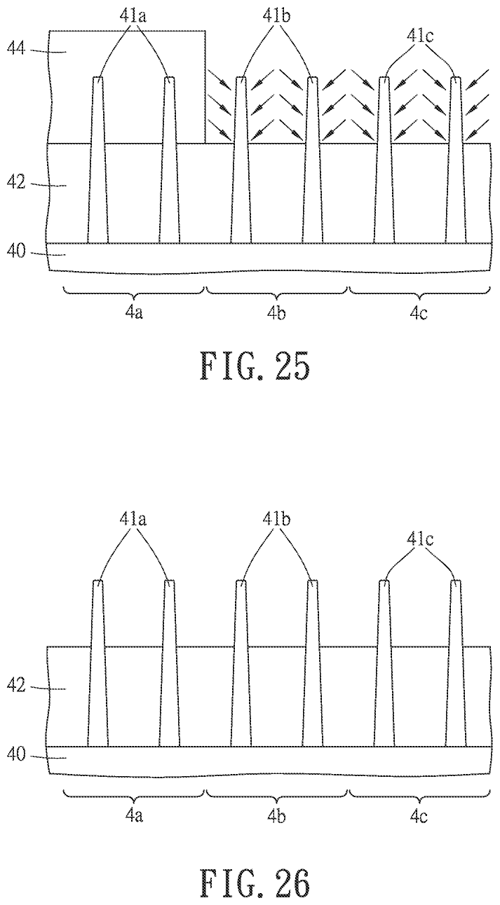

Referring to FIG. 20 and the example illustrated in FIG. 25, the method 100C then proceeds to step S25, where a patterned photoresist layer 44 is formed, followed by performing a nitrogen doping process. The patterned photoresist layer 44 is formed to cover the fin portions 41a in the first region 4a of the semiconductor substrate 40. The material and process for forming the patterned photoresist layer 44 may be the same as or similar to those for forming the patterned photoresist layer 14 as described in step S04 of the method 100A, and thus details thereof are omitted for the sake of brevity. The nitrogen doping process of step S25 may be performed in a manner similar to that as described in step S23. In this step, the nitrogen doping process is performed on the fin portions exposed from the patterned photoresist layer 44 (for example, the fin portions 41b, 41c in the second and third regions 4b, 4c of the semiconductor substrate 40).

Referring to FIG. 20 and the example illustrated in FIG. 26, the method 100C then proceeds to step S26, where the patterned photoresist layer 44 of the structure shown in FIG. 25 is removed. Step S26 may be performed by a suitable removal process, for example, but not limited to, an etching process, an ashing process, or other suitable removal processes.

Referring to FIG. 20 and the example illustrated in FIG. 27, the method 100C then proceeds to step S27, where a gate dielectric material layer 45 is formed on the structure shown in FIG. 26. The material and process for forming the gate dielectric material layer 45 may be the same as or similar to those for forming the first dielectric material film 13′, and thus details thereof are omitted for the sake of brevity. In some embodiments, after this step, an annealing process (for example, the annealing process as described in step S03 of the method 100A) may be performed on the structure shown in FIG. 27.

After step S27, the semiconductor device 200C is obtained. As shown in FIG. 27, in some embodiments, the gate dielectric material layer 45 may include a first gate dielectric layer 451 covering the fin portions 41a in the first region 4a of the semiconductor substrate 40, a second gate dielectric layer 452 covering the fin portions 41b in the second region 4b of the semiconductor substrate 40, and a third gate dielectric layer 453 covering the fin portions 41c in the third region 4c of the semiconductor substrate 40. In some embodiments, a thickness of the first gate dielectric layer 451 is greater than a thickness of the second gate dielectric layer 452, and the thickness of the second gate dielectric layer 452 is greater than a thickness of the third gate dielectric layer 453. It is noted that when the number of the nitrogen doping process performed on a fin portion increases, the deposition rate of the gate dielectric material layer 45 on the fin portion decreases. In this case, the fin portions 41c in the third region 4c of the semiconductor substrate 40 are subjected to the nitrogen doping process twice, the fin portions 41b in the second region 4b of the semiconductor substrate 40 are subjected to the nitrogen doping process once, and the fin portions 41a in the first region 4a of the semiconductor substrate 40 are not subjected to the nitrogen doping process. Therefore, the deposition rate of the gate dielectric material layer 45 on the fin portions 41c is slower than that of the gate dielectric material layer 45 on the fin portions 41a, 41b, and the deposition rate of the gate dielectric material layer 45 on the fin portions 41b is slower than that of the gate dielectric material layer 45 on the fin portions 41a. The thickness of the third gate dielectric layer 453 formed on the fin portions 41c is less than that of the second gate dielectric layer 452 formed on the fin portions 41b, and the thickness of the second gate dielectric layer 452 formed on the fin portions 41b is less than that of the first gate dielectric layer 451 formed on the fin portions 41a.

In some embodiments, when the thickness of the first gate dielectric layer 451 ranges from about 4 nm to about 8 nm, the fin portions 41a covered with the first gate dielectric layer 451 may be used for forming a FinFET to be applied in a high voltage electrical device (e.g., an I/O device having an operation voltage of about 3 V and a breakdown voltage of at least about 2.5 V). In some embodiments, when the thickness of the second gate dielectric layer 452 ranges from about 3 nm to about 5 nm, the fin portions 41b covered with the second gate dielectric layer 452 may be used for forming a FinFET to be applied in a low voltage electrical device (e.g., a core device having an operation voltage of about 1.8 V and a breakdown voltage of at least about 2.5 V). In some embodiments, when the thickness of the third gate dielectric layer 453 ranges from about 2 nm to about 5 nm, the fin portions 41c covered with the third gate dielectric layer 453 may be used for forming a FinFET to be applied in an electrical device having a low RTS.

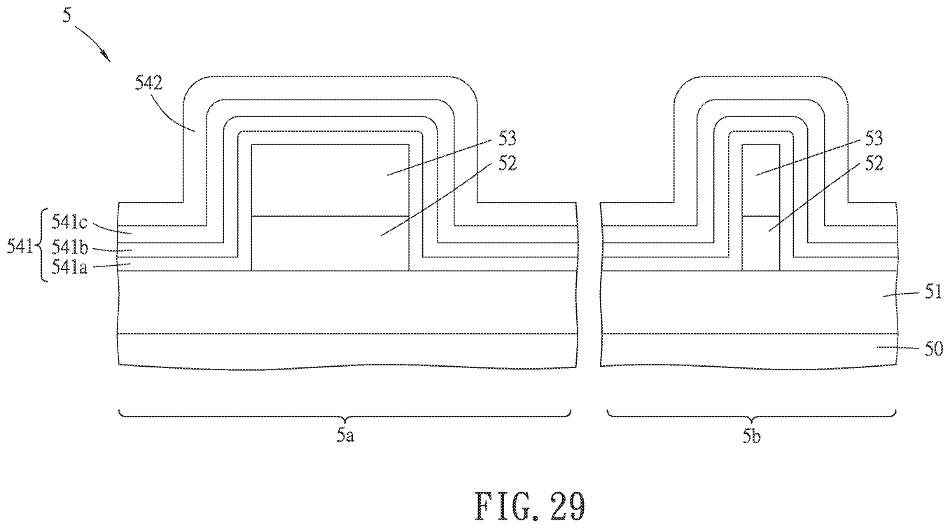

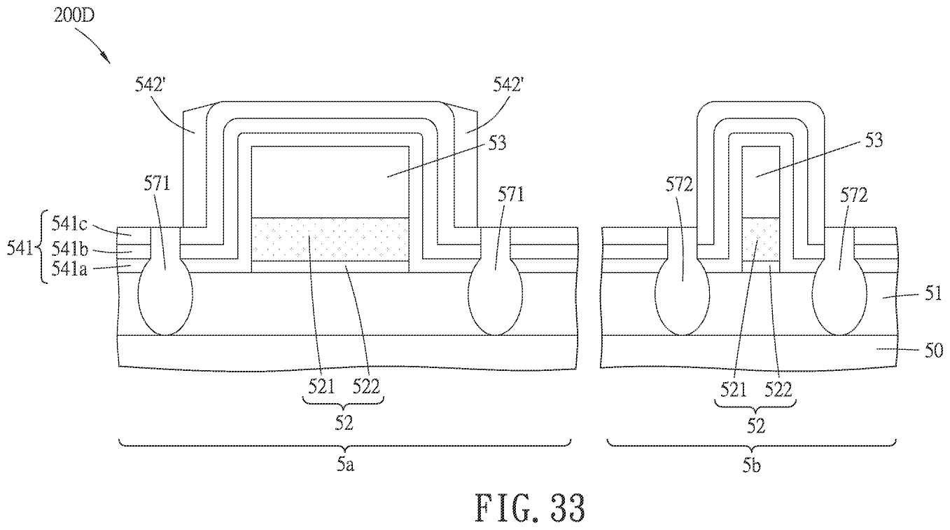

FIG. 28 is a flow diagram illustrating a method 100D for manufacturing a semiconductor device 200D shown in FIG. 33 in accordance with some embodiments. FIGS. 29 to 32 illustrate schematic views of some intermediate stages of the method 100D. Some portions may be omitted in FIGS. 29 to 32 for the sake of brevity. Additional steps can be provided before, after or during the method 100D, and some of the steps described herein may be replaced by other steps or be eliminated.

Referring to FIG. 28 and the example illustrated in FIG. 29, the method 100D begins at step S31, where a semiconductor workpiece 5 is formed. The semiconductor workpiece 5 includes a semiconductor substrate 50, a fin portion 51, a plurality of poly gate structures 52, a plurality of hard masks 53, a first spacer layer 541, and a second spacer layer 542.

The material of the semiconductor substrate 50 may be the same as or similar to that of the semiconductor substrate 10 as described in step S01 of the method 100A, and thus details thereof are omitted for the sake of brevity. In some embodiments, the semiconductor substrate 50 may include a first region 5a, and a second region 5b.

The fin portion 51 is disposed on the semiconductor substrate 50. In some embodiments, the fin portion 51 may be one of the fin portions 11a, 11b, 11c shown in FIG. 11, one of the fin portions 31a, 31b, 31c shown in FIG. 19, or one of the fin portions 41a, 41b, 41c shown in FIG. 27. The material of the fin portion 51 may be the same as or similar to that of the fin portions 11a, 11b, 11c as described in step S01 of the method 100A, and thus details thereof are omitted for the sake of brevity.

The poly gate structures 52 are disposed on the fin portion 51. The hard masks 53 are disposed respectively on the poly gate structures 52 opposite to the fin portion 51. In some embodiments, the hard masks 53 may include, for example, but not limited to, an oxide-based material (e.g., silicon oxide), a nitride-based material (e.g., silicon nitride), or a combination thereof. Other suitable materials for the hard masks 53 are within the contemplated scope of the present disclosure.

The first spacer layer 541 is disposed on the semiconductor substrate 50 and the fin portion 51, and covers the poly gate structures 52 and the hard masks 53. In some embodiments, the first spacer layer 541 includes a first spacer film 541a which is disposed on the semiconductor substrate 50 and the fin portion 51 and which covers the poly gate structures 52 and the hard masks 53, a second spacer film 541b conformally covering the first spacer film 541a, and a third spacer film 541c conformally covering the second spacer film 541b. Each of the first and second spacer films 541a, 541b may be made of an oxide-based material, for example, but not limited to, silicon oxide, silicon oxycarbide, silicon oxycarbonitride, or combinations thereof. The first and second spacer films 541a, 541b may be made of the same or different materials. The third spacer film 541c may be made of a nitride-based material, for example, but not limited to, silicon nitride. The second spacer layer 542 conformally covers the first spacer layer 541. The second spacer layer 542 may be made of an oxide-based material, for example, but not limited to, plasma-enhanced oxide. In some embodiments, the second spacer layer 542 may have a thickness ranging from about 20 Å to about 200 Å. Other suitable materials for each of the first spacer film 541a, the second spacer film 541b, the third spacer film 541c, and the second spacer layer 542 are within the contemplated scope of the present disclosure.

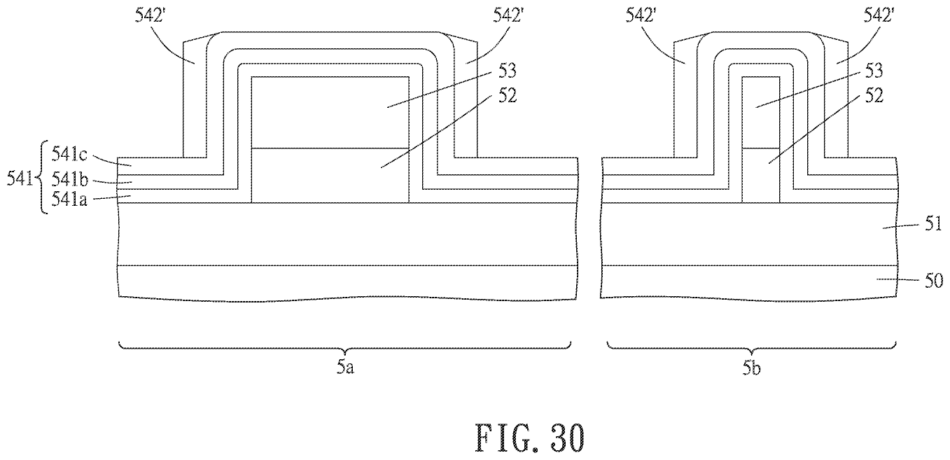

Referring to FIG. 28 and the example illustrated in FIG. 30, the method 100D then proceeds to step S32, where an etching process is performed to remove horizontal portions of the second spacer layer 542 so as to form a plurality of spacers 542′. In this step, the etching process may be an anisotropic etching process or other suitable etching processes. After this step, remaining portions of the second spacer layer 542 are formed into the spacers 542′. Two pairs of the spacers 542′ are shown in FIG. 30, where one pair of the spacers 542′ is located in the first region 5a and laterally covers vertical portions of the first spacer layer 541 in the first region 5a, and the other pair of the spacers 542′ is located in the second region 5b and laterally covers vertical portions of the first spacer layer 541 in the second region 5b.

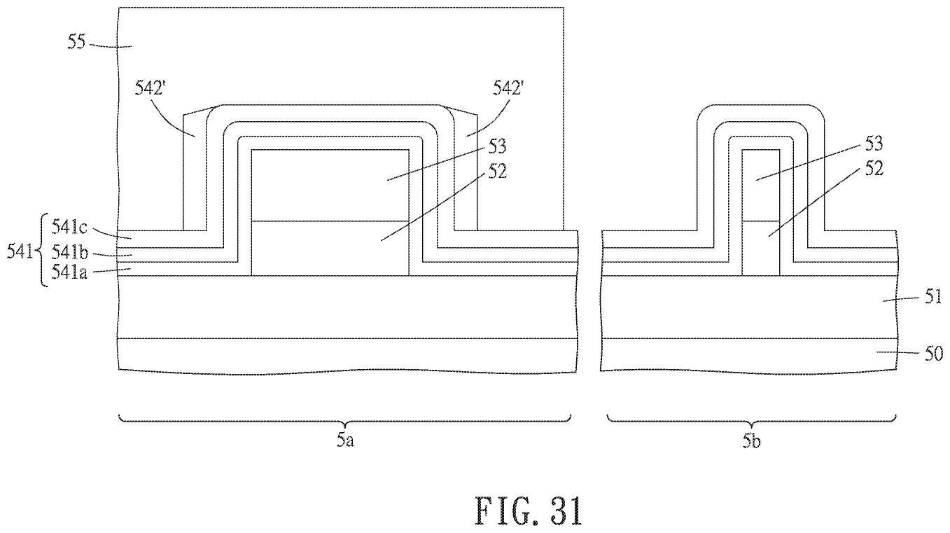

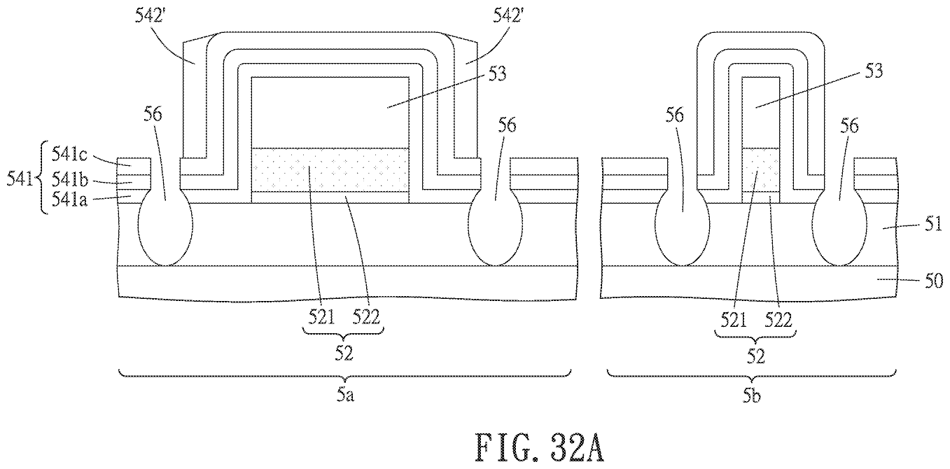

Referring to FIG. 28 and the example illustrated in FIG. 31, the method 100D then proceeds to step S33, where a patterned photoresist layer 55 is formed, followed by sequentially removing the spacers 542′ located in the second region 5b and the patterned photoresist layer 55. Step S33 may include sub-steps (i) to (iii).

In sub-step (i), the patterned photoresist layer 55 is formed to cover the structure located in the first region 5a. The material and process for forming the patterned photoresist layer 55 may be the same as or similar to those for forming the patterned photoresist layer 14 described in step S04 of the method 100A, and thus details thereof are omitted for the sake of brevity.

In sub-step (ii), the spacers 542′ located in the second region 5b are removed by a suitable etching process, for example, but not limited to, a dry etching process or other suitable etching processes.

In sub-step (iii), the patterned photoresist layer 55 is removed by a suitable removal process, for example, but not limited to, an etching process, an ashing process, or other suitable removal processes.

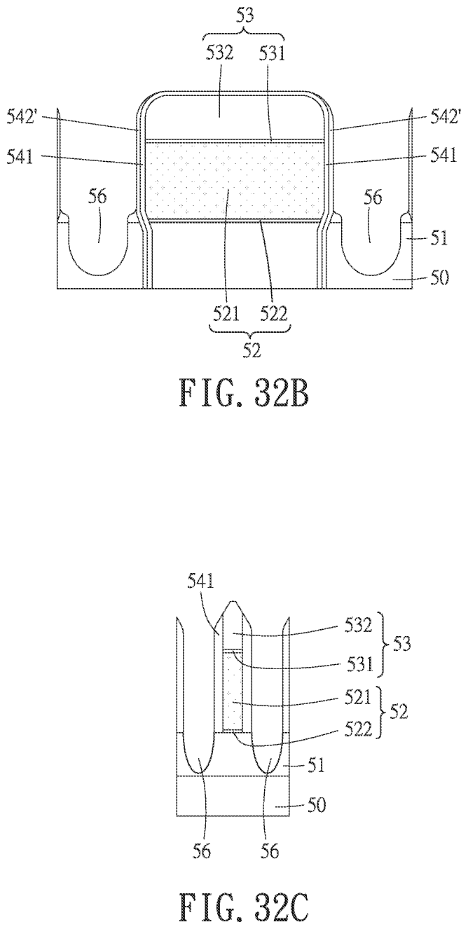

Referring to FIG. 28 and the example illustrated in FIGS. 32A to 32C, the method 100D then proceeds to step S34, where a plurality of source/drain recesses 56 are formed. FIGS. 32B and 32C are partially schematic views of FIG. 32A, where FIG. 32B shows a structure located in the first region 5a, in which epitaxial structures to be formed in a subsequent step are included, and FIG. 32C shows a structure located in the second region 5b. Step S34 may be performed by recessing the fin portion 51 using a suitable etching process, for example, but not limited to, an anisotropic dry etching process or other suitable etching processes, so as to form the source/drain recesses 56. Each pair of the source/drain recesses 56 is disposed at two opposite sides of a corresponding one of the poly gate structures 52. Each of the poly gate structures 52 includes a poly gate 521 and a gate dielectric 522 disposed below the poly gate 521 so that the poly gate 521 is separated from the fin portion 51 by the gate dielectric 522. The gate dielectric 522 may be formed by patterning one of the first gate dielectric layer 18, the second gate dielectric layer 19, and the third gate dielectric layer 20 shown in FIG. 11, one of the first gate dielectric layer 351, the second gate dielectric layer 352, and the third gate dielectric layer 353 shown in FIG. 19, or one of the first gate dielectric layer 451, the second gate dielectric layer 452, and the third gate dielectric layer 453 shown in FIG. 27 by a suitable etching process, for example, but not limited to, an anisotropic dry etching process or other suitable etching processes,

It is noted that the poly gate structure 52 disposed in the first region 5a is distal from adjacent ones of the source/drain recesses 56 due to formation of the spacers 542′ laterally covering the vertical portions of the first spacer layer 541 in the first region 5a, which is conducive to improving hot carrier injection (HCI) reliability of a FinFET structure subsequently formed in the first region 5a (which will be described hereinafter). In some embodiments, the FinFET structure may be used in a high voltage electrical device (e.g., an I/O device). As shown in FIGS. 32B and 32C, in some embodiments, each of the hard masks 53 may include a first hard mask portion 531 and a second hard mask portion 532 disposed on the first hard mask portion 531.

Referring to FIG. 28 and the example illustrated in FIG. 33, the method 100D then proceeds to step S35, where a plurality of source/drain features 571, 572 are formed in the source/drain recesses 56 (see FIG. 32A), respectively. Step S35 may be performed by one or more of epitaxial growth processes. The epitaxial growth process may be a selective epitaxial growth (SEG) process or other suitable epitaxial growth processes. In some embodiments, the source/drain features 571, 572 are made of crystalline silicon. Other suitable semiconductor materials for forming the source/drain features 571, 572 are within the contemplated scope of the present disclosure.

After step S35, the semiconductor device 200D is obtained. In some embodiments, a replacement gate process may be performed on the semiconductor device 200D. For example, the replacement gate process may include removing the poly gate 521 to form a void, followed by filling the void with a metallic material, so as to form a metal gate disposed on the gate dielectric 522. A plurality of metal gate structures (not shown) are formed accordingly.

In some embodiments, in the second region 5b of the semiconductor substrate 50, one of the metal gate structures, portions of the first spacer layer 541, and the source/drain features 572 may be cooperatively used in a core FinFET structure, which may be applied in a low voltage device (e.g., having an operation voltage of about 0.8 V and a breakdown voltage of at least about 2.5 V).

In some embodiments, in the first region 5a of the semiconductor substrate 50, one of the metal gate structures, the spacers 542′, portions of the first spacer layer 541, and the source/drain features 571 may be cooperatively used in an I/O FinFET structure, which may be applied in a high voltage device (e.g., having an operation voltage of about 3 V and a breakdown voltage of at least about 2.5 V). In some embodiments, by further forming a lightly doped region (not shown) beneath a corresponding one of the source/drain features 571 of the I/O FinFET structure, the breakdown voltage of the I/O FinFET structure may increase to greater than about 3 V.

In comparison with the core FinFET structure in the second region 5b of the semiconductor substrate 50, the I/O FinFET structure in the first region 5a of the semiconductor substrate 50 further includes the spacers 542′, which is conducive to increasing the breakdown voltage of the I/O FinFET structure.

In a semiconductor device of this disclosure, by forming a plurality of gate dielectric layers that respectively cover a plurality of fin portions on a semiconductor substrate and that have different thicknesses, one of the fin portions covered with a corresponding one of the gate dielectric layers that is relatively thick may be used for forming a FinFET to be applied in a high voltage electrical device (e.g., an I/O device), and one of the fin portions covered with a corresponding one of the gate dielectric layers that is relatively thin may be used for forming a FinFET to be applied in a low voltage electrical device (e.g., a core device) or an electrical device having a low RTS. In addition, in a semiconductor device (e.g., a FinFET device) that includes a spacer layer to laterally cover a metal gate structure and an additional spacer to laterally cover the spacer layer, the breakdown voltage and HCI reliability of the semiconductor device may be enhanced.

In accordance with some embodiments of the present disclosure, a method for manufacturing a semiconductor device includes: forming a first fin portion and a second fin portion on a semiconductor substrate, the first fin portion and the second fin portion being spaced apart from each other; and forming a first gate dielectric layer and a second gate dielectric layer on the first fin portion and the second fin portion, respectively, the first gate dielectric layer having a first thickness, the second gate dielectric layer having a second thickness different from the first thickness.

In accordance with some embodiments of the present disclosure, formation of the first gate dielectric layer and the second gate dielectric layer includes: forming a first dielectric material film to cover the first fin portion and the second fin portion; forming a patterned photoresist layer to cover a portion of the first dielectric material film on the first fin portion; removing a remaining portion of the first dielectric material film exposed from the patterned photoresist layer so as to form a first gate dielectric film on the first fin portion; removing the patterned photoresist layer; and forming a second gate dielectric film on the first gate dielectric film and the second fin portion, so as to form the first gate dielectric layer on the first fin portion and the second gate dielectric layer on the second fin portion. The first gate dielectric layer includes the first gate dielectric film and a first portion of the second gate dielectric film disposed on the first gate dielectric film. The second gate dielectric layer includes a second portion of the second gate dielectric film. The first thickness of the first gate dielectric layer is greater than the second thickness of the second gate dielectric layer.

In accordance with some embodiments of the present disclosure, formation of the first gate dielectric layer and the second gate dielectric layer includes: forming a patterned photoresist layer to cover the first fin portion; treating the second fin portion with a fluorine doping process; removing the patterned photoresist layer; and forming a gate dielectric material film on the first fin portion and the second fin portion, so as to form the first gate dielectric layer on the first fin portion and the second gate dielectric layer on the second fin portion. The first thickness of the first gate dielectric layer is less than the second thickness of the second gate dielectric layer.

In accordance with some embodiments of the present disclosure, the fluorine doping process is conducted by implantation or thermal diffusion.

In accordance with some embodiments of the present disclosure, the fluorine doping process is conducted by implantation at an energy ranging from about 1 KeV to about 400 KeV.

In accordance with some embodiments of the present disclosure, the fluorine doping process is conducted by implantation at a dose ranging from about 1×10¹⁰ atoms/cm² to about 1×10¹⁶ atoms/cm².

In accordance with some embodiments of the present disclosure, formation of the first gate dielectric layer and the second gate dielectric layer includes: forming a patterned photoresist layer to cover the first fin portion; treating the second fin portion with a nitrogen doping process; removing the patterned photoresist layer; and forming a gate dielectric material film on the first fin portion and the second fin portion, so as to form the first gate dielectric layer on the first fin portion and the second gate dielectric layer on the second fin portion. The first thickness of the first gate dielectric layer is greater than the second thickness of the second gate dielectric layer.

In accordance with some embodiments of the present disclosure, the nitrogen doping process is conducted by implantation or thermal diffusion.

In accordance with some embodiments of the present disclosure, the nitrogen doping process is conducted by implantation at an energy ranging from about 1 KeV to about 400 KeV.

In accordance with some embodiments of the present disclosure, the nitrogen doping process is conducted by implantation at a dose ranging from about 1×10¹⁰ atoms/cm² to about 1×10¹⁶ atoms/cm².

In accordance with some embodiments of the present disclosure, a method for manufacturing a semiconductor device includes: forming a first fin portion and a second fin portion on a semiconductor substrate, the first fin portion and the second fin portion being spaced apart from each other; forming a first gate dielectric layer and a second gate dielectric layer on the first fin portion and the second fin portion, respectively, the first gate dielectric layer having a first thickness, the second gate dielectric layer having a second thickness different from the first thickness; and forming a first gate structure and a second gate structure on the first fin portion, the second fin portion, or each of the first fin portion and the second fin portion. Each of the first gate structure and the second gate structure includes a gate dielectric, which is formed by patterning a corresponding one of the first gate dielectric layer and the second gate dielectric layer.

In accordance with some embodiments of the present disclosure, a method for manufacturing a semiconductor device further includes: conformally forming a first spacer layer to cover the first fin portion, the second fin portion, the first gate structure, and the second gate structure; and forming a pair of spacers to laterally cover vertical portions of the first spacer layer, which laterally cover one of the first gate structure and the second gate structure.

In accordance with some embodiments of the present disclosure, formation of the spacers includes: conformally forming a second spacer layer on the first spacer layer; removing horizontal portions of the second spacer layer by an etching process to form a plurality of the spacers laterally covering the vertical portions of the first spacer layer, which laterally cover the first gate structure and the second gate structure; forming a patterned photoresist layer to cover the spacers laterally covering the vertical portions of the first spacer layer, which laterally cover the first gate structure; removing the spacer laterally covering the vertical portions of the first spacer layer, which laterally cover the second gate structure; and removing the patterned photoresist layer.

In accordance with some embodiments of the present disclosure, formation of the first gate dielectric layer and the second gate dielectric layer includes: forming a first dielectric material film to cover the first fin portion and the second fin portion; forming a patterned photoresist layer to cover a portion of the first dielectric material film on the first fin portion; removing a remaining portion of the first dielectric material film exposed from the patterned photoresist layer so as to form a first gate dielectric film on the first fin portion; removing the patterned photoresist layer; and forming a second gate dielectric film on the first gate dielectric film and the second fin portion, so as to form the first gate dielectric layer on the first fin portion and the second gate dielectric layer on the second fin portion. The first gate dielectric layer includes the first gate dielectric film and a first portion of the second dielectric material film disposed on the first gate dielectric film. The second gate dielectric layer includes a second portion of the second gate dielectric film. The first thickness of the first gate dielectric layer is greater than the second thickness of the second gate dielectric layer.

In accordance with some embodiments of the present disclosure, formation of the first gate dielectric layer and the second gate dielectric layer includes: forming a patterned photoresist layer to cover the first fin portion; treating the second fin portion with a fluorine doping process; removing the patterned photoresist layer; and forming a gate dielectric material film on the first fin portion and the second fin portion, so as to form the first gate dielectric layer on the first fin portion and the second gate dielectric layer on the second fin portion. The first thickness of the first gate dielectric layer is less than the second thickness of the second gate dielectric layer.

In accordance with some embodiments of the present disclosure, formation of the first gate dielectric layer and the second gate dielectric layer includes: forming a patterned photoresist layer to cover the first fin portion; treating the second fin portion with a nitrogen doping process; removing the patterned photoresist layer; and forming a gate dielectric material film on the first fin portion and the second fin portion, so as to form the first gate dielectric layer on the first fin portion and the second gate dielectric layer on the second fin portion. The first thickness of the first gate dielectric layer is greater than the second thickness of the second gate dielectric layer.

In accordance with some embodiments of the present disclosure, a semiconductor device includes a semiconductor substrate, a first fin portion, a second fin portion, a first gate dielectric layer, and a second gate dielectric layer. The first fin portion and the second fin portion are disposed on the semiconductor substrate and are spaced apart from each other. The first gate dielectric layer is disposed on the first fin portion and has a first thickness. The second gate dielectric layer is disposed on the second fin portion, and has a second thickness different from the first thickness of the first gate dielectric layer.

In accordance with some embodiments of the present disclosure, each of the first thickness and the second thickness ranges from about 0.1 nm to about 10 nm.

In accordance with some embodiments of the present disclosure, the first thickness of the first gate dielectric layer is less than the second thickness of the second gate dielectric layer, and the second fin portion is doped with a plurality of fluorine ions.

In accordance with some embodiments of the present disclosure, the first thickness of the first gate dielectric layer is greater than the second thickness of the second gate dielectric layer, and the second fin portion is doped with a plurality of nitrogen ions.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a first fin portion and a second fin portion on a semiconductor substrate, the first fin portion and the second fin portion being spaced apart from each other; and
forming a first gate dielectric layer and a second gate dielectric layer on the first fin portion and the second fin portion, respectively, the first gate dielectric layer having a first thickness, the second gate dielectric layer having a second thickness different from the first thickness.

2. The method as claimed in claim 1, wherein formation of the first gate dielectric layer and the second gate dielectric layer includes:
forming a first dielectric material film to cover the first fin portion and the second fin portion;
forming a patterned photoresist layer to cover a portion of the first dielectric material film on the first fin portion;
removing a remaining portion of the first dielectric material film exposed from the patterned photoresist layer so as to form a first gate dielectric film on the first fin portion;
removing the patterned photoresist layer; and
forming a second gate dielectric film on the first gate dielectric film and the second fin portion, so as to form the first gate dielectric layer on the first fin portion and the second gate dielectric layer on the second fin portion, the first gate dielectric layer including the first gate dielectric film and a first portion of the second gate dielectric film disposed on the first gate dielectric film, the second gate dielectric layer including a second portion of the second gate dielectric film, the first thickness of the first gate dielectric layer being greater than the second thickness of the second gate dielectric layer.

3. The method as claimed in claim 1, wherein formation of the first gate dielectric layer and the second gate dielectric layer includes:
forming a patterned photoresist layer to cover the first fin portion;
treating the second fin portion with a fluorine doping process;
removing the patterned photoresist layer; and
forming a gate dielectric material film on the first fin portion and the second fin portion, so as to form the first gate dielectric layer on the first fin portion and the second gate dielectric layer on the second fin portion, the first thickness of the first gate dielectric layer being less than the second thickness of the second gate dielectric layer.

4. The method as claimed in claim 3, wherein the fluorine doping process is conducted by implantation or thermal diffusion.

5. The method as claimed in claim 4, wherein the fluorine doping process is conducted by implantation at an energy ranging from 1 KeV to 400 KeV.

6. The method as claimed in claim 4, wherein the fluorine doping process is conducted by implantation at a dose ranging from 1×10¹⁰ atoms/cm² to 1×10¹⁶ atoms/cm².

7. The method as claimed in claim 1, wherein formation of the first gate dielectric layer and the second gate dielectric layer includes:
forming a patterned photoresist layer to cover the first fin portion;
treating the second fin portion with a nitrogen doping process;
removing the patterned photoresist layer; and
forming a gate dielectric material film on the first fin portion and the second fin portion, so as to form the first gate dielectric layer on the first fin portion and the second gate dielectric layer on the second fin portion, the first thickness of the first gate dielectric layer being greater than the second thickness of the second gate dielectric layer.

8. The method as claimed in claim 7, wherein the nitrogen doping process is conducted by implantation or thermal diffusion.

9. The method as claimed in claim 8, wherein the nitrogen doping process is conducted by implantation at an energy ranging from 1 KeV to 400 KeV.

10. The method as claimed in claim 8, wherein the nitrogen doping process is conducted by implantation at a dose ranging from 1×10¹⁰ atoms/cm² to 1×10¹⁶ atoms/cm².

11. A method for manufacturing a semiconductor device, comprising:
forming a first fin portion and a second fin portion on a semiconductor substrate, the first fin portion and the second fin portion being spaced apart from each other;
forming a first gate dielectric layer and a second gate dielectric layer on the first fin portion and the second fin portion, respectively, the first gate dielectric layer having a first thickness, the second gate dielectric layer having a second thickness different from the first thickness; and
forming a first gate structure and a second gate structure on the first fin portion, the second fin portion, or each of the first fin portion and the second fin portion, each of the first gate structure and the second gate structure including a gate dielectric, which is formed by patterning a corresponding one of the first gate dielectric layer and the second gate dielectric layer.

12. The method as claimed in claim 11, further comprising:
conformally forming a first spacer layer to cover the first fin portion, the second fin portion, the first gate structure, and the second gate structure; and
forming a pair of spacers to laterally cover vertical portions of the first spacer layer, which laterally cover one of the first gate structure and the second gate structure.

13. The method as claimed in claim 12, wherein formation of the spacers includes:
conformally forming a second spacer layer on the first spacer layer;
removing horizontal portions of the second spacer layer by an etching process to form a plurality of the spacers laterally covering the vertical portions of the first spacer layer, which laterally cover the first gate structure and the second gate structure;
forming a patterned photoresist layer to cover the spacers laterally covering the vertical portions of the first spacer layer, which laterally cover the first gate structure;
removing the spacer laterally covering the vertical portions of the first spacer layer, which laterally cover the second gate structure; and
removing the patterned photoresist layer.

14. The method as claimed in claim 11, wherein formation of the first gate dielectric layer and the second gate dielectric layer includes:
forming a first dielectric material film to cover the first fin portion and the second fin portion;
forming a patterned photoresist layer to cover a portion of the first dielectric material film on the first fin portion;
removing a remaining portion of the first dielectric material film exposed from the patterned photoresist layer so as to form a first gate dielectric film on the first fin portion;
removing the patterned photoresist layer; and
forming a second gate dielectric film on the first gate dielectric film and the second fin portion, so as to form the first gate dielectric layer on the first fin portion and the second gate dielectric layer on the second fin portion, the first gate dielectric layer including the first gate dielectric film and a first portion of the second gate dielectric film disposed on the first gate dielectric film, the second gate dielectric layer including a second portion of the second gate dielectric film, the first thickness of the first gate dielectric layer being greater than the second thickness of the second gate dielectric layer.

15. The method as claimed in claim 11, wherein formation of the first gate dielectric layer and the second gate dielectric layer includes:
forming a patterned photoresist layer to cover the first fin portion;
treating the second fin portion with a fluorine doping process;
removing the patterned photoresist layer; and
forming a gate dielectric material film on the first fin portion and the second fin portion, so as to form the first gate dielectric layer on the first fin portion and the second gate dielectric layer on the second fin portion, the first thickness of the first gate dielectric layer being less than the second thickness of the second gate dielectric layer.

16. The method as claimed in claim 11, wherein formation of the first gate dielectric layer and the second gate dielectric layer includes:
forming a patterned photoresist layer to cover the first fin portion;
treating the second fin portion with a nitrogen doping process;
removing the patterned photoresist layer; and
forming a gate dielectric material film on the first fin portion and the second fin portion, so as to form the first gate dielectric layer on the first fin portion and the second gate dielectric layer on the second fin portion, the first thickness of the first gate dielectric layer being greater than the second thickness of the second gate dielectric layer.

17. A semiconductor device, comprising:
a semiconductor substrate;
a first fin portion and a second fin portion disposed on the semiconductor substrate and spaced apart from each other;
a first gate dielectric layer disposed on the first fin portion and having a first thickness; and
a second gate dielectric layer disposed on the second fin portion and having a second thickness different from the first thickness of the first gate dielectric layer.

18. The semiconductor device as claimed in claim 17, wherein each of the first thickness and the second thickness ranges from 0.1 nm to 10 nm.

19. The semiconductor device as claimed in claim 17, wherein the first thickness of the first gate dielectric layer is less than the second thickness of the second gate dielectric layer, and the second fin portion is doped with a plurality of fluorine ions.

20. The semiconductor device as claimed in claim 17, wherein the first thickness of the first gate dielectric layer is greater than the second thickness of the second gate dielectric layer, and the second fin portion is doped with a plurality of nitrogen ions.
